(19) United States
(12) Patent Application Publication
(10) Pub. No.: US 2010/0270650 A1
(43) Pub. Date: Oct. 28, 2010

(54) Silicon substrate with periodical structure

(75) Inventors: Chung-Hua Li, Taipei City (TW); Sheng-Ru Lee, Taipei City (TW)

Correspondence Address: BACON & THOMAS, PLLC, 625 SLATERS LANE, FOURTH FLOOR, ALEXANDRIA, VA, 22314-1176, US

(73) Assignee: Aurotek Corporation, Taipei (TW)

(21) Appl. No.: 12/662,542

(22) Filed: Apr. 22, 2010

(30) Foreign Application Priority Data
Apr. 27, 2009 (TW) 098113871

(51) Int. Cl. H01L 29/30; H01L 21/302

(52) U.S. Cl. 257/618; 438/689; 257/E29.106; 257/E21.214

(57) ABSTRACT

A silicon substrate with periodical structure is disclosed, which comprises: a silicon substrate, and at least one periodical structure formed on at least one surface of the silicon substrate and having plural micro-cavities; wherein, the micro-cavities are arranged in an array, the micro-cavities are each in an inverted awl-shape or an inverted truncated cone-shape, the length of the base line of the micro-cavities in the inverted awl-shape is 100˜2400 nm, the diameter of the micro-cavities in the inverted truncated cone-shape is 100˜2400 nm, and the depth of the micro-cavities is 100˜2400 nm.

### BACKGROUND OF THE INVENTION

1. Field of the Invention

The present invention relates to a silicon substrate with a periodical structure and, more particularly, to a silicon substrate with a periodical structure formed by nano-sized balls, which can be used for depositing an anti-reflection layer thereon to form a crystalline silicon solar cell.

2. Description of Related Art

With the development of industrial technology, the serious problems that the whole world is facing today are the energy crisis and the environmental pollution. In order to solve the global energy crisis and to reduce the environmental pollution, a lot of efforts are being made on alternative energy, such as wind power and solar energy, to replace fossil fuel sources. In particular, the solar cell is one of the effective means, which can convert the solar energy into electricity.

FIGS. 1A to 1F show the general process for preparing the silicon solar cell. First, as shown in FIG. 1A, a silicon substrate 10 is provided, wherein the silicon substrate 10 is a P-type silicon substrate. Next, the silicon substrate 10 is patterned to form a rough surface thereon, as shown in FIG. 1B. Then, a process of phosphor diffusion is performed on the surface of the silicon substrate 10 to form a P-N junction. After the P-N junction is formed on the surface of the silicon substrate 10, a process of evaporation coating is performed to form an anti-reflection layer 13 of the surface of the silicon substrate 10. In addition, another anti-reflection layer 14 can be selectively formed on the anti-reflection layer 13, as shown in FIG. 1D. When the anti-reflection layers 13, 14 are made of silicon nitride, the anti-reflection layers 13, 14 can also serve as passivation layers. Then, two front electrodes 15 are formed on the surface of the anti-reflection layer 14, and a bake electrode 16 is formed under the silicon substrate 10 through screen printing process, as shown in FIG. 1E. Finally, a silicon solar cell is obtained after heat treatment.

In addition, the production cost of the silicon substrate is high and about a half of the total production cost of the solar cell, so the selling price of the solar cell cannot be reduced. Hence, scientists try to find ways, which can improve the photoelectric conversion efficiency of the solar cell and decrease the production cost thereof. Currently, one way for improving the photoelectric conversion efficiency of the solar cell is to increase the light absorption area. For example, silicon nano-wires can be used as a material to increase the area reacting with incident photons. Alternatively, an anti-reflection structure, which can increase the amount of incident photons, also can be used for improving the photoelectric conversion efficiency of the solar cell. Generally, the silicon substrate is patterned by a complex photo mask and an etching process, to form micro-cavities with awl shapes on the surface of the silicon substrate. Then, an anti-reflection layer is formed on the surface of the micro-cavities through a process of evaporation coating, and then an anti-reflection structure is obtained, as shown in FIG. 1C.

Currently, the patterned surface of the silicon substrate is formed though photolithography and followed by wet etching or dry etching. The process for patterning the silicon substrate is shown in FIGS. 2A to 2F. First, referring to FIG. 2A, a silicon substrate 10 is provided; and a photo-resist layer 11 is formed on the surface 101 of the silicon substrate 10, as shown in FIG. 2B. Next, a photo-mask 12 is provided on the photo-resist layer 11, followed by exposing to pattern the photo-resist layer 11, as shown in FIG. 2C. After developing and removing the photo-mask 12, a patterned photo-resist layer 11 is obtained, as shown in FIG. 2D. A reactive ion etching (RIE) process is performed to etch the silicon substrate 10 by using the patterned photo-resist layer 11 as an etching template, and then plural micro-cavities 102 are formed on the surface of the silicon substrate 10, as shown in FIG. 2E. After removing the photo-resist layer 11 (etching template), a patterned silicon substrate 10 is obtained, as shown in FIG. 2F. Herein, the plural micro-cavities formed on the surface 101 of the patterned silicon substrate 10 are arranged in a periodical structure.

Although the method of dry etching can produce a silicon substrate having a periodical structure with uniform and regular micro-cavities, there are still some disadvantages with the aforementioned process. First, the manufacturing cost of photolithography is high and the production rate is low. Further, if a nano-sized periodical structure is desired, a photo-mask with sub-micro size is required in the photolithography process. However, the photo-mask with sub-micro size is very expensive, and the manufacturing cost of the photo-mask is even more expensive when a periodical structure with a size of 500 nm or less is desired. In addition, the RIE machine is costly, the RIE process is slow, and the silicon substrate is damaged easily when the RIE process is used

In order to solve the problem caused by the dry etching process, a method of wet etching is developed to form a silicon substrate with a periodical structure, as shown in FIGS. 3A to 3F. The wet etching process for forming a silicon substrate with a periodical structure is similar to the dry etching process, except an etching buffer is used to pattern the silicon substrate. As shown in FIGS. 3A to 3D, a patterned photo-resist layer 11 is formed after exposing and development (photolithography). Then, a non-isotropic etching buffer is used to etch the silicon substrate 10 by using the patterned photo-resist layer 11 as an etching template, and then plural micro-cavities 102 are formed on the surface of the silicon substrate 10, as shown in FIG. 3F. Finally, the patterned photo-resist layer 11 (etching template) is removed, and a patterned silicon substrate 10 is obtained, as shown in FIG. 3F. Herein, the plural micro-cavities 102 formed on the surface 101 of the patterned silicon substrate 10 are arranged in a periodical structure. It should be noted that the micro-cavities 102 with inverted awl-shape are obtained, when the silicon substrate 10 is patterned by a wet etching process.

The wet etching process can protect the silicon substrate from damage and the surface of the patterned silicon substrate is a natural lattice plane, but the uniformity of the periodical structure is not good enough if the parameter of the wet etching process is not controlled properly. In addition, the photolithography is still performed in the aforementioned process, so the problems of high manufacturing cost and low production rate still exist. Hence when the patterned silicon substrate used in the solar cell is prepared by photolithography and wet etching process, the manufacturing cost cannot be reduced a lot. Furthermore, the production rate cannot be improved much if photolithography still used in the process for preparing the patterned silicon substrate.

When the patterned silicon substrate is prepared by the aforementioned method, the problems of slow production rate and high manufacturing cost still exist. Therefore, it is desirable to provide a silicon substrate with a patterned surface formed by rapid and low cost process, in order to reduce the manufacturing cost of the solar cell.

### SUMMARY OF THE INVENTION

The object of the present invention is to provide a silicon substrate with a periodical structure, which can be prepared in a low-cost and high-quantity way, and can be applied widely on anti-reflection layers of solar cells.

To achieve the object, the silicon substrate with the periodical structure of the present invention comprises: a silicon substrate; and at least one periodical structure formed on at least one surface of the silicon substrate, and having plural micro-cavities, wherein, the micro-cavities are arranged in an array, the micro-cavities are each in an inverted awl-shape or an inverted truncated cone-shape, the length of the base line of the micro-cavities in the inverted awl-shape is 100˜2400 nm, the diameter of the micro-cavities in the inverted truncated cone-shape is 100˜2400 nm, and the depth of the micro-cavities is 100˜2400 nm. Herein, the inverted awl means that the base of the awl is located on the surface of the silicon substrate, and the apex of the awl is hollowed from the surface of the silicon substrate.

According to the silicon substrate with the periodical structure of the present invention, the periodical structure is formed by the following steps: (A) providing the silicon substrate and plural nano-sized balls, wherein the nano-sized balls are arranged on a surface of the silicon substrate; (B) depositing a cladding layer on a partial surface of the silicon substrate and the gaps between the nano-sized balls; (C) removing the nano-sized balls; (D) etching the silicon substrate by using the cladding layer as an etching template; and (E) removing the etching template to form the periodical structure on the surface of the silicon substrate.

According to the silicon substrate with the periodical structure of the present invention, the nano-sized balls are used for replacing the process of photolithography to form the periodical structure. The nano-sized balls can arranged automatically and uniformly on the surface of the silicon substrate, due to the property of “self-assembling” of the nano-sized balls. The well-arranged nano-sized balls can serve as a template for forming an etching template. Because the silicon substrate of the present invention is produced by the arranged nano-sized balls, not by the expensive photo-mask with sub-micro size, so it is possible to produce the silicon substrate with the periodical structure inexpensively and rapidly in the present invention.

The silicon substrate with the periodical structure of the present invention may further comprise an anti-reflection layer deposited on the surfaces of the silicon substrate and the micro-cavities. The anti-reflective layer can be formed on the surfaces of the silicon substrate and the micro-cavities by conventional methods, such as evaporation coating, chemical vapor deposition (CVD), or physical vapor deposition (PVD). Furthermore, the material of the anti-reflection layer can be any material used in the solar cell generally, such as, ITO, AZO, ZnO, SnOₓ, TiOₓ, SiOₓ, SiNₓ, or SiOₓN_{y}, wherein x is 0.1˜2, and y is 0.1˜2. Because the anti-reflection layer can be used to increase the incident photon flux, the efficiency of the solar cell can be increased. In addition, the material of the silicon substrate may be P-type single crystalline silicon, N-type single crystalline silicon, P-type polycrystalline silicon, N-type polycrystalline silicon, P-type amorphous silicon, or N-type amorphous silicon.

According to the silicon substrate with the periodical structure of the present invention, the step (A) of arranging the nano-sized balls on the surface of the silicon substrate comprises the following steps: (A1) providing the silicon substrate, and a colloid solution in a container, wherein the colloid solution comprises the nano-sized balls and a surfactant; (A2) placing the silicon substrate in the container, and the colloid solution covering the surface of the silicon substrate; and (A3) adding a volatile solution into the container to obtain the silicon substrate with the nano-sized balls formed thereon. Herein, the nano-sized balls are arranged in at least one nano-sized ball layer. Preferably, the nano-sized balls are arranged in a single layer of the nano-sized ball layer.

According to the silicon substrate of the present invention, the sizes of the micro-cavities on the silicon substrate are determined by the etching condition and the diameters of the nano-sized balls. Preferably, the diameter of the nano-sized balls is 100 nm˜2.5 μm. More preferably, the diameter of the nano-sized balls is 100 nm˜1.2 μm. In addition, all the nano-sized balls have the same diameters, preferably. Furthermore, the material of the nano-sized balls is unlimited, and can be silicon oxides, ceramics, PMMA, titanium oxides, or PS.

According to the silicon substrate of the present invention, the cladding layer can be deposited on a partial surface of the silicone substrate and the gaps between the nano-sized balls by use of a general thin film deposition apparatus or a general electrochemical deposition apparatus. Preferably, the cladding layer is formed through chemical vapor deposition (CVD) or physical vapor deposition (PVD). In addition, the material of the cladding layer is unlimited, and can be any material generally used for etching templates. Preferably, the material of the cladding layer is silicon oxides, silicon nitrides, silicon oxynitrides, Ti, Ag, Au, Pt, Mo, Cu, Pd, Fe, Ni, Sn, W, V, ITO, ZnO, AZO, or photoresist (PR). Further, the thickness of the cladding layer is adjusted according to the size of the desired micro-cavities. Preferably, the thickness of the cladding layer is shorter than the diameter of the nano-sized balls.

According to the silicon substrate of the present invention, the process of dry etching or wet etching can be used for etching the silicon substrate in the step (D). Preferably, the process of wet etching is used, in order to prevent the silicon substrate from becoming damaged. In the process of wet etching, the silicon substrate is etched by an etching buffer. The etching buffer can be an acidic or alkaline etching buffer generally used, and is selected according to the material of the cladding layer. The acidic etching buffer can comprise an acidic solution, an alcohol, and water, and the alkaline etching buffer can comprise an alkaline solution, an alcohol, and water. Preferably, the acidic solution is a mixture solution of HNO₃ and HF, or Amine Callates containing ethanolamine, gallic acid, water, hydrogen peroxide, and a surfactant. Preferably, the alkaline solution is a solution of NaOH, KOH, NH₄OH, CeOH, RbOH, (CH₃)₄NOH, C₂H₄(NH₂)₂, or N₂H₄. In addition, the alcohol can be ethanol or isopropanol.

Hence, the silicon substrate with the periodical structure of the present invention is formed by using nano-sized balls and wet etching process, not by photolithography. Hence, the photo mask with sub-micro size is not needed when preparing the silicon substrate of the present invention, so it is possible to reduce the manufacturing cost and the production time greatly. At the same time, the periodical structure having plural micro-cavities is formed by a wet etching process, so it is possible to prevent the silicon substrate from being damaged. Hence, the present invention can provide a silicon substrate with a periodical structure, which can be formed easily and inexpensively. Furthermore, the periodical structure on the surface of the silicon substrate has highly uniformity, so the efficiency of the solar cell using the silicon substrate of the present invention can be improved greatly.

In addition, the present invention further provides a silicon substrate having an etching template with a periodical structure, comprising: a silicon substrate; and an etching template, disposed on a surface of the silicon substrate, wherein, the etching template has a periodical structure formed on the surface of the etching template and having plural micro-cavities, and the micro-cavities are arranged in an array.

According to the silicon substrate having the etching template with the periodical structure of the present invention, the shapes of the micro-cavities are partial spheres. Preferably, the micro-cavities are in half-sphere shape. In addition, the diameters of the micro-cavities in the half-sphere shape may be 100 nm˜2400 nm. Preferably, the diameters of the micro-cavities are 100 nm˜1000 nm. Furthermore, the material of the etching template may be silicon oxides, silicon nitrides, silicon oxynitrides, Ti, Ag, Au, Pt, Mo, Cu, Pd, Fe, Ni, Sn, W, V, ITO, ZnO, AZO, or photoresist (PR).

When the silicon substrate having the etching template with the periodical structure of the present invention is used, the micro-cavities on the silicon substrate can be formed in different shapes through adjusting the time and the temperature condition of the etching process. Hence, the obtained silicon substrate with the micro-cavities in different shapes can be applied on silicon solar cells for different purposes.

Other objects, advantages, and novel features of the invention will become more apparent from the following detailed description when taken in conjunction with the accompanying drawings.

### BRIEF DESCRIPTION OF THE DRAWINGS

FIGS. 1A to 1E are cross-sectional views illustrating a process for manufacturing a silicon solar cell in the art;

FIGS. 2A to 2F are cross-sectional views illustrating a process for manufacturing a silicon substrate with a periodical structure by use of a dry etching process in the art;

FIGS. 3A to 3F are cross-sectional views illustrating a process for manufacturing a silicon substrate with a periodical structure by use of a non-isotropic wet etching method in the art;

FIGS. 4A to 4F are cross-sectional views illustrating a process that nano-sized balls are arranged on a surface of a silicon substrate in a preferred embodiment of the present invention;

FIGS. 5A to 5E are cross-sectional views illustrating a process for manufacturing a silicon substrate with a periodical structure in a preferred embodiment of the present invention;

FIG. 6 is a perspective view of a silicon substrate with a periodical structure of a preferred embodiment of the present invention;

FIG. 7 is a perspective view of a silicon substrate with a periodical structure coating an anti-reflection layer thereon in a preferred embodiment of the present invention;

FIG. 8 is a perspective view of a silicon substrate with a periodical structure of another preferred embodiment of the present invention; and

FIG. 9 is a perspective view of a solar cell, which uses a silicon substrate with a periodical structure of a preferred embodiment of the present invention.

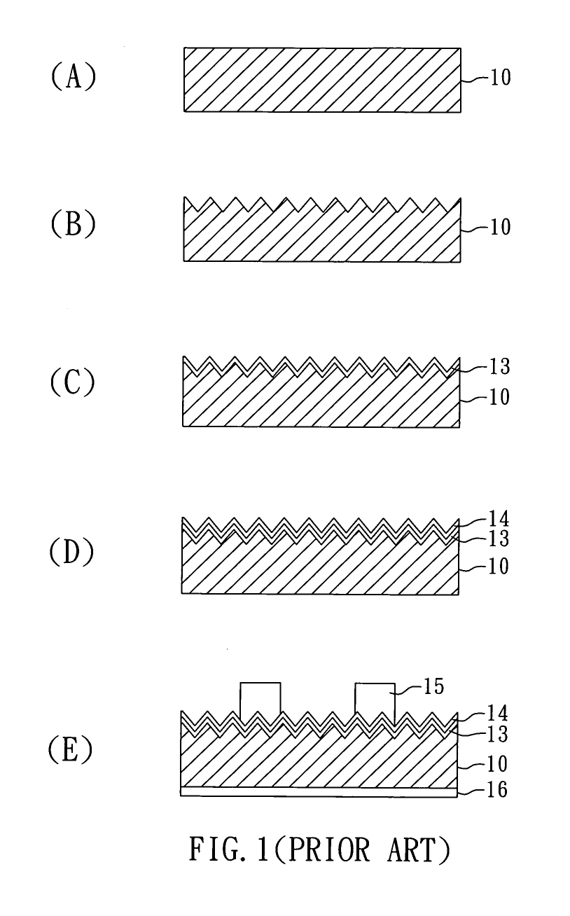

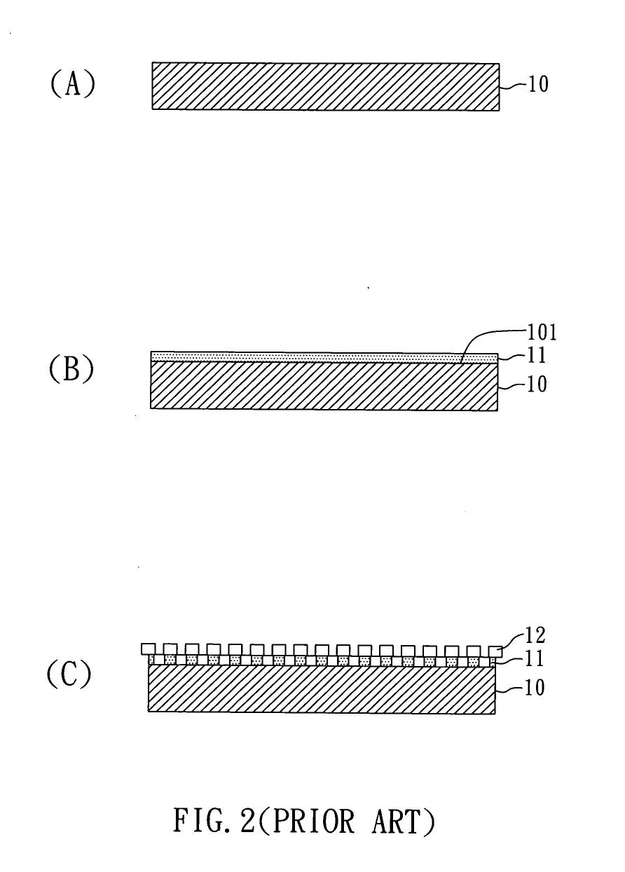

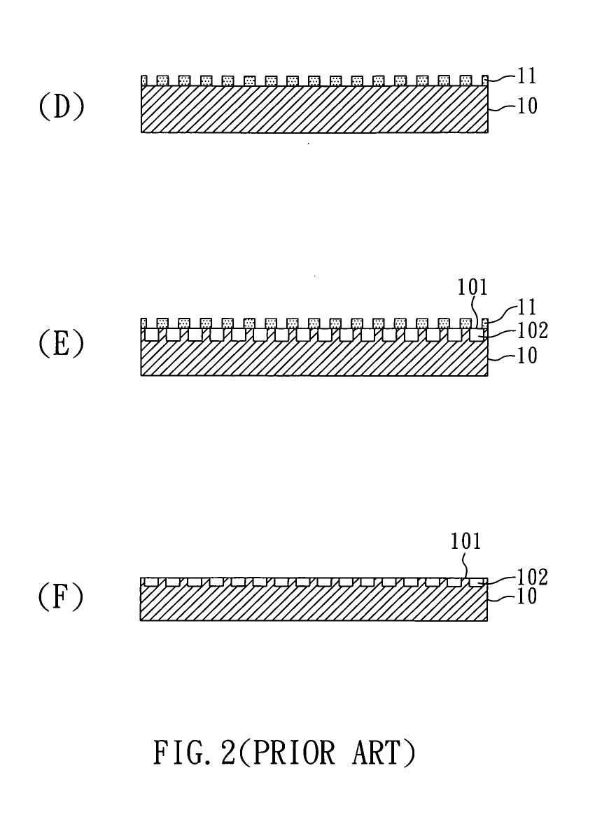

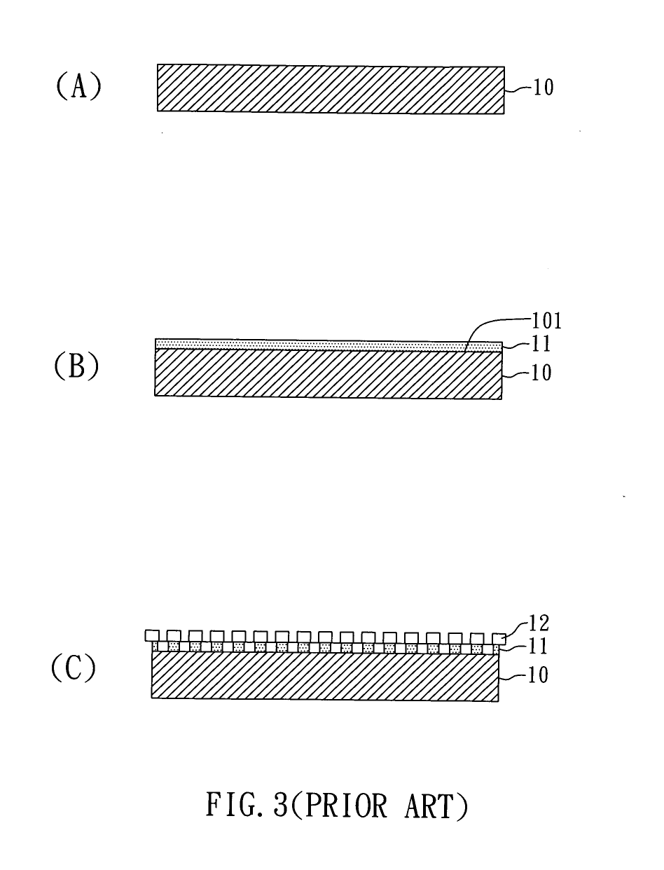

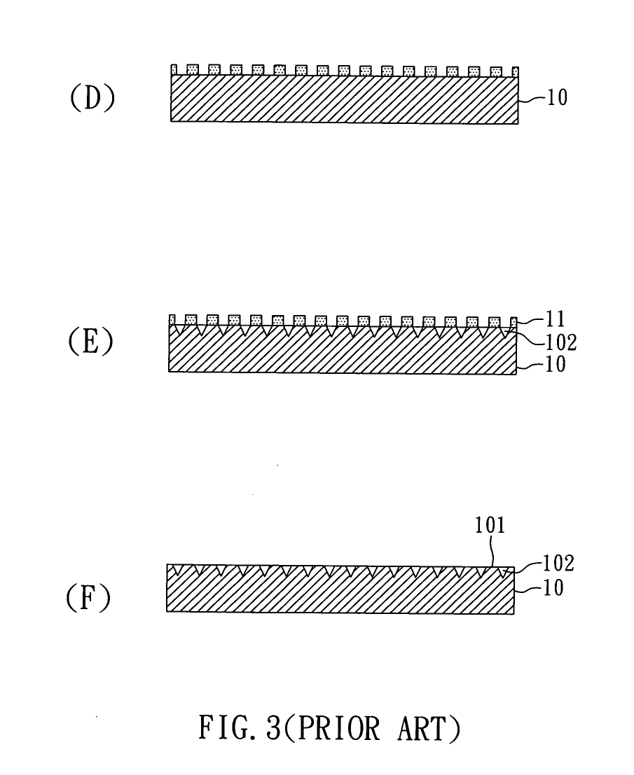

### DETAILED DESCRIPTION OF THE PREFERRED EMBODIMENT

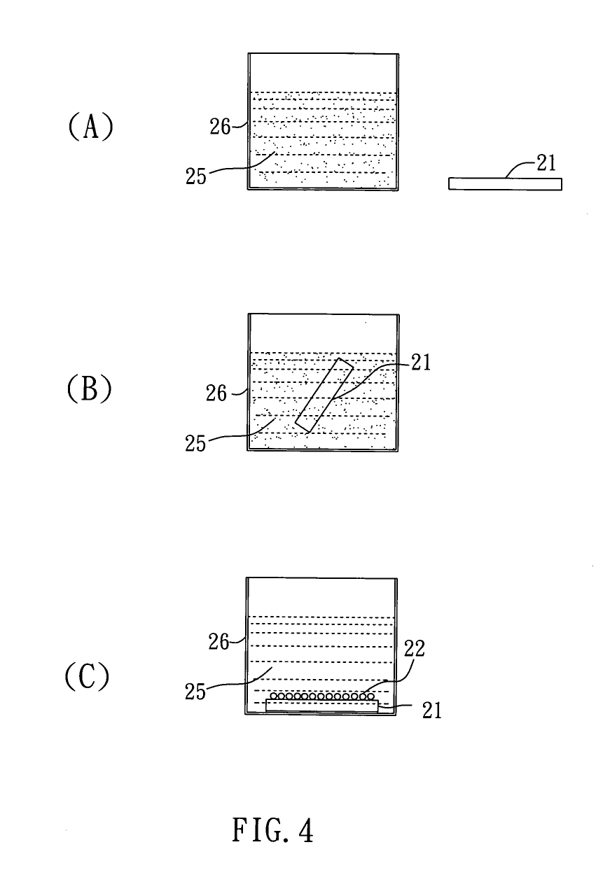

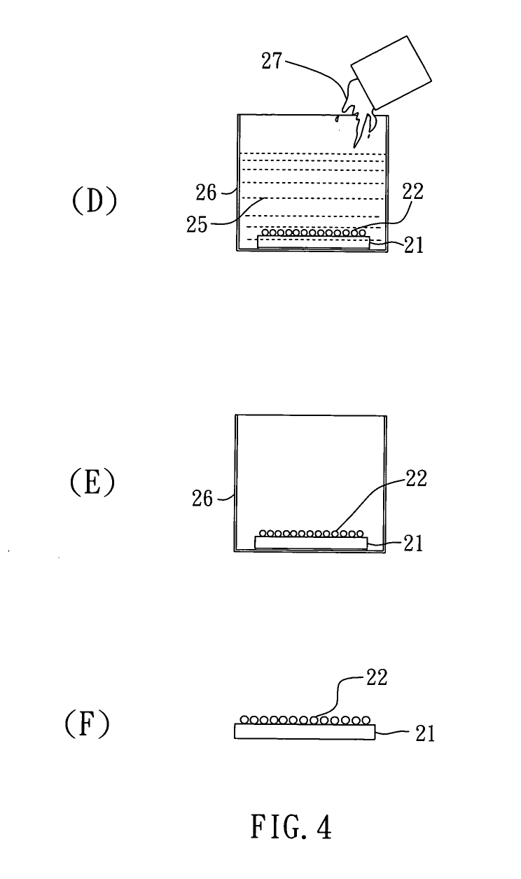

FIGS. 4A to 4F are cross-sectional views illustrating a process in which nano-sized balls are arranged on a surface of a silicon substrate in a preferred embodiment of the present invention. First, as shown in FIG. 4A, a silicon substrate 21 is provided, and a colloid solution 25 is provided in a container 26, wherein the colloid solution 25 comprises plural nano-sized balls (not shown in the figure) and a surfactant (not shown in the figure). Next, the silicon substrate 21 is placed in the container 26, and the silicon substrate 21 is immersed in the colloid solution 25 entirely, as shown in FIG. 4B. After several minutes, the nano-sized balls 22 are arranged on the surface of the substrate 21 orderly to form a “nano-sized ball layer”, as shown in FIG. 4C. Then, a volatile solution 27 is added into the container 26 to evaporate the colloid solution 25 totally, as shown in FIG. 4D. Finally, after the colloid solution 25 is evaporated completely, as shown in FIG. 4E, the silicon substrate 21 is taken out from the container 26, and a silicon substrate 21 with plural nano-sized balls 22 orderly arranged thereon is obtained, as shown in FIG. 4F.

In the present embodiment, the material of the nano-sized balls 22 is poly-styrene (PS). However, the material of the nano-sized balls 22 can be ceramics, metal oxides such as TiOₓ, poly(methyl methacrylate) (PMMA), or glass material such as SiOₓ, according to different application demands. In addition, the diameters of the nano-sized balls 22 are 100 nm˜2.5 μm, and the diameters of the majority of nano-sized balls 22 are the same. In the present embodiment, the diameters of the nano-sized balls 22 are 900 nm, and almost all the nano-sized balls 22 have the same diameter. However, in different application demands, the sizes of the nano-sized balls 22 are not limited to the aforementioned range.

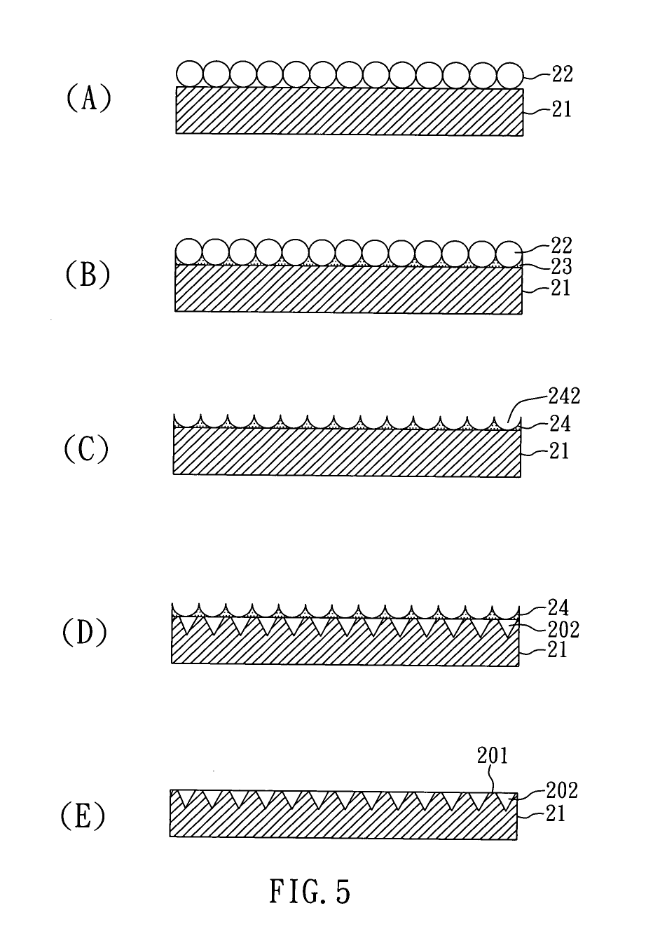

FIGS. 5A to 5F are each cross-sectional views illustrating a process for manufacturing a silicon substrate with a periodical structure in a preferred embodiment of the present invention. First, as shown in FIG. 5A, a silicon substrate 21 and plural nano-sized balls 22 are provided. According to the aforementioned method, the nano-sized balls 22 are arranged in order on the surface of the silicon substrate 21 to form a nano-sized ball layer. The nano-sized balls 22 also can be arranged on the surface of the silicon substrate 21 in a form of multiple layers. In the present embodiment, the nano-sized balls 22 are arranged on the surface of the silicon substrate 21 in the form of a single layer.

Next, a cladding layer 23 is deposited on apartial surface of the silicon substrate 21 and the gaps between the nano-sized balls 22 through CVD, as shown in FIG. 5B. Herein, the thickness of the cladding layer 23 is less than the diameter of the nano-sized balls 22. Further, the material of the cladding layer 23 is silicon oxide. However, the cladding layer 23 can be formed not only by CVD, but also by PVD. Moreover, the material of the cladding layer 23 can be any kind of metal or silicon material, which is ordinarily used in an etching template. For example, the material of the cladding layer can be silicon oxides, silicon nitrides, silicon oxynitrides, Ti, Ag, Au, Pt, Mo, Cu, Pd, Fe, Ni, Sn, W, V, ITO, ZnO, AZO, or photoresist (PR).

Then, the nano-sized balls 22 are removed by using a THF solution, and the residual cladding layer 23 serves as an etching template 24, as shown in FIG. 5C. Hence, a silicon substrate having an etching template with a periodical structure is obtained, which comprises: a silicon substrate 21; and an etching template 24 disposed on the surface of the silicon substrate 21. The etching template 24 has a periodical structure formed on the surface of the etching template 24 and has plural micro-cavities 242, and the micro-cavities 242 are arranged in an array.

It should be noted that the nano-sized balls with different materials are removed from the substrate by different suitable solutions. For example, the nano-sized balls made of PMMA can be removed by toluene or formic acid, and the nano-sized balls made of silicon oxide (silica) can be removed by using HF or a solution containing HF.

Then, as shown in FIG. 5D, the cladding layer is used as an etching template 24 to pattern the silicon substrate 21 through a method of wet etching. In the present embodiment, the etching buffer comprises NaOH, isopropanol, and water. However, the etching buffer used for wet etching is selected according to the material of the cladding layer. Preferably, the acidic etching buffer comprises an acidic solution, which can be a mixture solution of HNO₃ and HF, or Amine Callates containing ethanolamine, gallic acid, water, pyrazine, hydrogen peroxide, and a surfactant. Furthermore, the alkaline etching buffer comprises an alkaline solution, which can be a solution of NaOH, KOH, NH₄OH, CeOH, RbOH, (CH₃)₄NOH, C₂H₄(NH₂)₂, or N₂H₄. Preferably, the alcohol can be ethanol or isopropanol. In addition, as the components and the concentration of the etching buffer, and the temperature and the time of the etching process are changed, the patterns formed on the silicon substrate are different. As the temperature of etching process is increased, the etching time is decreased. In the present embodiment, the temperature of the etching process is 70° C., and the etching time is 1 min.

After the etching template 24 is removed, plural micro-cavities 202, i.e. a periodical structure, are formed on the surface of the silicon substrate 21, as shown in FIG. 5E. The micro-cavities 202 are arranged in an array, and the micro-cavities 202 are in inverted awl-shape. Herein, the inverted awl means that the base of the awl is located on the surface 201 of the silicon substrate 21, and the apex of the awl is hollowed from the surface 201 of the silicon substrate 21.

The SEM image of the patterned silicon substrate shows that the micro-cavities each with an inverted awl-shaped are formed on the silicon substrate in the present embodiment. The length of the side of the base is about 300 nm, and the depth of the micro-cavities is about 250 nm. The SEM image shows that the periodical structure formed on the silicon substrate of the present embodiment is a nano-sized periodical structure.

When the etching process is performed under 70° C. for 5 min, the length of the side of the base is about 590 nm, and the depth of the micro-cavities is about 570 nm, which is determined by the SEM image.

Further, when the etching process is performed under 70° C. for 10 min, the length of the side of the base is about 680 nm, and the depth of the micro-cavities is about 620 nm, which is determined by the SEM image. After the etching process is performed under 70° C. for 10 min, the silicon substrate with the periodical structure in the best state is obtained.

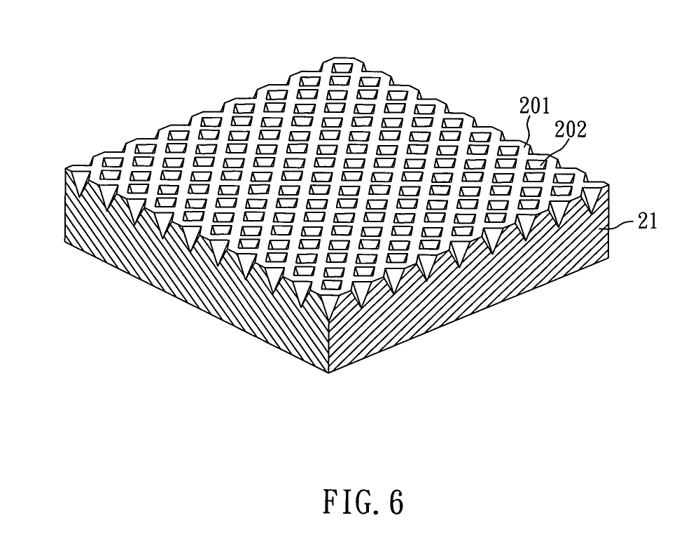

In order to understand the periodical structure formed on the silicon substrate of the present embodiment, please refer to FIG. 6, which is a perspective view of a silicon substrate with a periodical structure in a preferred embodiment of the present invention. The silicon substrate with the periodical structure prepared according to the aforementioned method comprises plural micro-cavities 202, which are arranged in an array on the surface 201 of the silicon substrate 21 and each formed in an inverted awl-shape (i.e. inverted pyramid-shape).

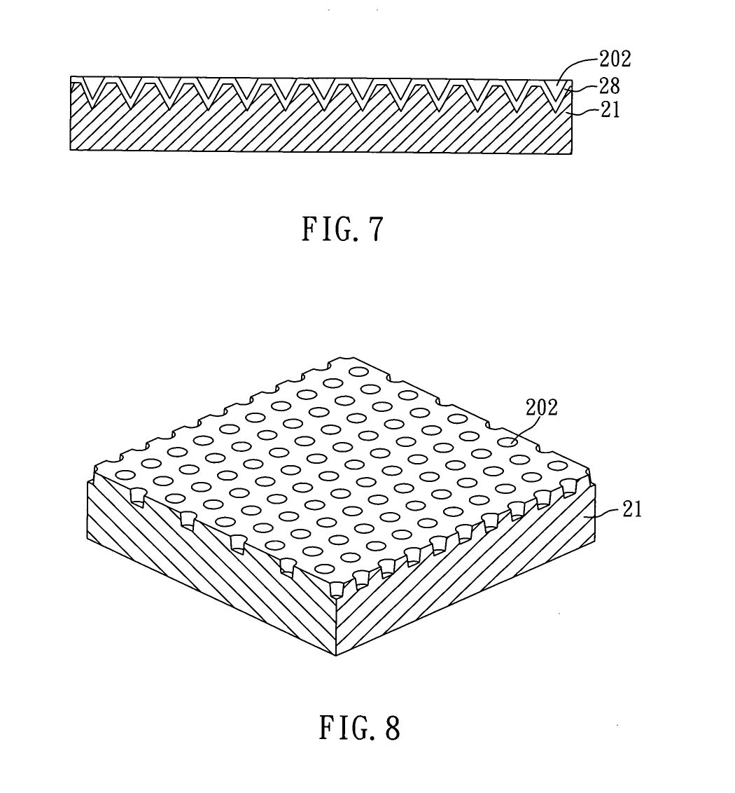

Then, an anti-reflection layer 28 is formed on the surface of the silicon substrate 21 with the periodical structure, as shown in FIG. 7. The material of the anti-reflection layer 28 can be ITO, AZO, ZnO, SnOₓ, TiOₓ, SiOₓ, SiNₓ, or SiOₓN_{y}, x is 0.1˜2, and y is 0.1˜2. In the present embodiment, ITO is deposited on the surface of the silicon substrate 21 by use of CVD.

Next, the reflection coefficient of the silicon substrate coating with the anti-reflection layer of the present embodiment is measured, wherein the length of the base of the micro-cavities is about 680 nm, and the depth of the micro-cavities is about 620 nm. Under the wavelength of 300 to 900 nm, the reflection coefficient of the silicon substrate coating with the anti-reflection layer of the present embodiment is about 10%; and the reflection coefficient of the silicon substrate coating with the anti-reflection layer of the present embodiment is about 3% under the wavelength of 500 to 700 nm. However, the reflection coefficient of the silicon substrate formed by photolithography is about 20% under the wavelength of 300 to 900 nm. Hence, the reflection coefficient of the patterned silicon substrate of the present embodiment is much better than that of the patterned silicon substrate prepared by photolithography. Therefore, the efficiency of the solar cell can be improved greatly when the silicon substrate with the periodical structure of the present invention is used.

FIG. 8 is a perspective view of a silicon substrate with a periodical structure of another preferred embodiment of the present invention. The silicon substrate is patterned by the same method as illustrated above, except that the etching buffer is a mixture solution of HNO₃ and HF. The mixture solution of HNO₃ and HF is an isotropic etching buffer, so the micro-cavities in inverted truncated cone-shape can be obtained in the present embodiment.

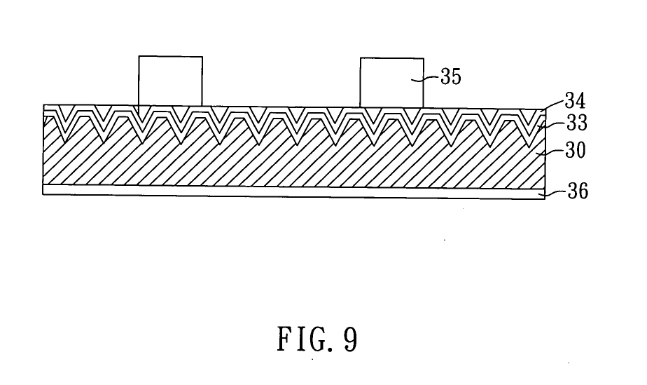

FIG. 9 is a perspective view of a solar cell, which uses a silicon substrate with a periodical structure of a preferred embodiment of the present invention. The solar cell comprises: a silicon substrate 30, which is made of a P-type silicon substrate, and has plural micro-cavities 302 formed thereon; anti-reflection layers 33, 34 disposed on the surfaces of the silicon substrate 30 and the micro-cavities 302, wherein the material of the anti-reflection layer 33 is TiO₂, the material of the anti-reflection layer 34 is SiN, and the anti-reflection layer 34 made of SiN can also serve as a passivation layer; two front electrodes 35 formed on the surface of the anti-reflection layer 34; and one back electrode 36 formed under the silicon substrate 30.

In conclusion, the silicon substrate with the periodical structure of the present invention can be produced in a rapid and inexpensive way, by using the nano-sized balls as an etching template. Because the photolithography, which is expensive and time-consuming, is not performed when the silicon substrate is patterned in the present invention, the manufacturing cost and the production time can be reduced greatly. In addition, as the size of the pattern is smaller, the photo-mask used in the photolithography is more expensive. However, the nano-sized balls used in the present invention are very cheap. Furthermore, the size of the nano-sized balls can be adjusted easily according to the size of the periodical structure, which is desired to form on the surface of the silicon substrate. Compared to the dry etching process requiring expensive equipment, the silicon substrate with the periodical structure of the present invention is formed by use of a wet etching process, which can reduce the manufacturing cost and improve the process safety, and also can prevent the substrate from being damaged. When the silicon substrate with the periodical structure of the present invention is widely applied on the solar cell, the efficiency of the solar cell can be increased about 20˜30%.

Although the present invention has been explained in relation to its preferred embodiment, it is to be understood that many other possible modifications and variations can be made without departing from the scope of the invention as hereinafter claimed.

What is claimed is:

1. A silicon substrate with a periodical structure, comprising:
a silicon substrate; and
at least one periodical structure formed on at least one surface of the silicon substrate, and having plural micro-cavities,
wherein, the micro-cavities are arranged in an array, the micro-cavities are each in an inverted awl-shape or an inverted truncated cone-shape, the length of the base line of the micro-cavities in the inverted awl-shape is 100˜2400 nm, the diameter of the micro-cavities in the inverted truncated cone-shape is 100˜2400 nm, and the depth of the micro-cavities is 100˜2400 nm.

2. The silicon substrate as claimed in claim 1, wherein the periodical structure is formed by the following steps:
(A) providing the silicon substrate and plural nano-sized balls, wherein the nano-sized balls are arranged on a surface of the silicon substrate;
(B) depositing a cladding layer on a partial surface of the silicon substrate and the gaps between the nano-sized balls;
(C) removing the nano-sized balls;
(D) etching the silicon substrate by using the cladding layer as an etching template; and
(E) removing the etching template to form the periodical structure on the surface of the silicon substrate.

3. The silicon substrate as claimed in claim 1, wherein the periodical structure is a nano-sized periodical structure.

4. The silicon substrate as claimed in claim 1, further comprising an anti-reflection layer deposited on the surfaces of the silicon substrate and the micro-cavities.

5. The silicon substrate as claimed in claim 1, wherein the material of the anti-reflection layer is ITO, AZO, ZnO, SnOₓ, TiOₓ, SiOₓ, SiNₓ, or SiOₓN_{y}, x is 0.1˜2, and y is 0.1˜2.

6. The silicon substrate as claimed in claim 1, wherein the material of the silicon substrate is P-type single crystalline silicon, N-type single crystalline silicon, P-type polycrystalline silicon, N-type polycrystalline silicon, P-type amorphous silicon, or N-type amorphous silicon.

7. The silicon substrate as claimed in claim 2, wherein the step (A) of arranging the nano-sized balls on the surface of the silicon substrate comprises the following steps:
(A1) providing the silicon substrate, and a colloid solution in a container, wherein the colloid solution comprises the nano-sized balls and a surfactant;
(A2) placing the silicon substrate in the container, and the colloid solution covering the surface of the silicon substrate; and
(A3) adding a volatile solution into the container to obtain the silicon substrate with the nano-sized balls formed thereon.

8. The silicon substrate as claimed in claim 2, wherein the cladding layer is formed on a partial surface of the silicon substrate and the gaps between the nano-sized balls through CVD or PVD.

9. The silicon substrate as claimed in claim 2, wherein the silicon substrate is etched by an etching solution in the step (D).

10. The silicon substrate as claimed in claim 9, wherein the etching buffer comprises an alkaline solution, an alcohol, and water.

11. The silicon substrate as claimed in claim 10, wherein the alkaline solution is a solution of NaOH, KOH, NH₄OH, CeOH, RbOH, (CH₃)₄NOH, C₂H₄(NH₂)₂, or N₂H₄.

12. The silicon substrate as claimed in claim 10, wherein the alcohol is ethanol or isopropanol.

13. The silicon substrate as claimed in claim 9, wherein the etching buffer comprises an acidic solution, an alcohol, and water.

14. The silicon substrate as claimed in claim 13, wherein the acidic solution is a mixture solution of HNO₃ and HF, or Amine Callates containing ethanolamine, gallic acid, water, hydrogen peroxide, and a surfactant.

15. The silicon substrate as claimed in claim 13, wherein the etching buffer comprises an acidic solution, an alcohol, and water.

16. The silicon substrate as claimed in claim 1, the material of the cladding layer is silicon oxides, silicon nitrides, silicon oxynitrides, Ti, Ag, Au, Pt, Mo, Cu, Pd, Fe, Ni, Sn, W, V, ITO, ZnO, AZO, or photoresist.

17. The silicon substrate as claimed in claim 2, wherein the material of the nano-sized balls is silicon oxides, ceramics, PMMA, titanium oxides, or PS.

18. The silicon substrate as claimed in claim 2, wherein the thickness of the cladding layer is less than the diameters of the nano-sized balls.

19. The silicon substrate as claimed in claim 2, wherein the diameters of the nano-sized balls are 100 nm˜2.5 μm.

20. The silicon substrate as claimed in claim 2, wherein the diameters of the nano-sized balls are the same.

21. A silicon substrate having an etching template with a periodical structure, comprising:
a silicon substrate; and
an etching template, disposed on a surface of the silicon substrate,
wherein, the etching template has a periodical structure formed on the surface of the etching template and having plural micro-cavities, and the micro-cavities are arranged in an array.

22. The silicon substrate as claimed in claim 21, wherein the micro-cavities are in half-sphere shape.

23. The silicon substrate as claimed in claim 21, wherein the diameters of the micro-cavities are 100 nm˜2400 nm.

24. The silicon substrate as claimed in claim 21, wherein the material of the etching template is silicon oxides, silicon nitrides, silicon oxynitrides, Ti, Ag, Au, Pt, Mo, Cu, Pd, Fe, Ni, Sn, W, V, ITO, ZnO, AZO, or photoresist.
